(19) United States
(12) Patent Application Publication
(10) Pub. No.: US 2016/0072026 A1
(43) Pub. Date: Mar. 10, 2016

(54) LIGHT EMITTING DEVICE UTILIZING SEMICONDUCTOR AND MANUFACTURING METHOD OF THE SAME

(71) Applicant: NS MATERIALS CORP., Fukuoka (JP)

(72) Inventor: Eiichi Kanaumi, Chikushino-shi, Fukuoka (JP)

(73) Assignee: NS Materials Inc., Chikushino-shi, Fukuoka (JP)

(21) Appl. No.: 14/427,512

(22) PCT Filed: Jun. 12, 2013
(86) PCT No.: PCT/JP2013/066217

§ 371 Date: Oct. 23, 2015

(30) Foreign Application Priority Data
Sep. 11, 2012 (JP) 2012-199845

(51) Int. Cl. H01L 33/50; H01L 33/54

(52) U.S. Cl. CPC H01L 33/507; H01L 33/54; H01L 2933/0041; H01L 2933/005

(57) ABSTRACT

An LED light emitting apparatus 1 includes a base substrate 2, a blue LED chip 3, a circuit pattern 4, a transmissive protection layer 5, a first fluorescent layer 6, and a second fluorescent layer 7.

### TECHNICAL FIELD

The present invention relates to a light emitting device utilizing a semiconductor, and a manufacturing method of the same. In detail, the present invention relates to a light emitting device utilizing a semiconductor which has both a protection performance of a light emitting element and a light emitting characteristic, and a manufacturing method of the same.

### BACKGROUND ART

An LED element (light emitting diode) is a semiconductor element that emits light by application of a voltage, and is widely used due to high brightness, long life, and a characteristic of obtaining light not containing unnecessary ultraviolet rays or infrared rays. As a use thereof, the LED element is applied to a lighting device as well as a headlight of an automobile, a backlight of an electronic device, various displays, and the like.

The light emitted from the LED element is monochromatic light of a frequency corresponding to a bandgap of a chemical compound forming a semiconductor. Therefore, since a wavelength of the emitted light is changed in accordance with the kind of chemical compound, LED elements that emit various emitting light colors are manufactured. As the chemical compound, for example, Ga (gallium), N (nitrogen), In (indium), Al (aluminum), P (phosphorous), and the like are used.

A method of generating white light with use of an LED element has been examined. White light is light that contains a continuous spectrum over the entire visible light region. Meanwhile, the LED element only emits light having a wavelength in a certain narrow range. Thus, light of a continuous spectrum is not easily emitted by a single LED element.

However, human vision recognizes a mixed color of three peak wavelengths corresponding to three primary colors of light or two peak wavelengths of complementary colors as white light. By utilizing this visual characteristic, a white LED whose emitting light color is recognized as white color is manufactured.

As a representative white LED, there is a white LED of a fluorescent body type in which a fluorescent body and an LED element that emits blue light or ultraviolet light are combined. This white LED has such a structure that the LED element that emits blue light or ultraviolet light is sealed by the fluorescent body made of resin containing a fluorescent material or the like.

Part of light emitted from the LED element is converted into light of a predetermined wavelength by the fluorescent body, and the other part of the light is emitted as it is. These two kinds of light are mixed and recognized as white light by human vision.

Under such circumstances, a technique relating to a light emitting device capable of emitting light of a desired wavelength with use of semiconductor quantum dots is proposed (for example, refer to Patent Document 1). Patent Document 1 describes a light emitting device in which semiconductor quantum dots are included in a fluorescent body sealing an LED element.

The semiconductor quantum dots are very small semiconductor particles having a maximum particle diameter of 50 nm or less. The semiconductor quantum dots have such a structure that inside a semiconductor crystal of a nano-size, electrons are confined in a state of having a discrete energy level quantity. The semiconductor quantum dots absorb photons of energy greater than a bandgap (energy difference between a valence band and a conduction band), and emit light having a wavelength corresponding to the grain diameter thereof. That is, by having a property of absorbing light of a fixed wavelength or less and controlling the grain diameter, light of various wavelengths can be generated.

The size of the semiconductor quantum dots is minute. Thus, the semiconductor quantum dots can be highly densely generated in the light emitting device, so that the light emitting device can have high fluorescence efficiency. The fluorescence efficiency indicates a ratio of the number of photons of emitted light relative to the number of photons of inputted light.

Specifically, Patent Document 1 describes an LED light emitting apparatus 100 as shown in FIG. 9. In this LED light emitting apparatus 100, a first sealing layer 104 and a second sealing layer 105 in which semiconductor quantum dots 102, 103 are dispersed are formed in an upper part of a light source 101. The apparatus serves as a light emitting device in which the semiconductor quantum dots absorbing light of the light source 101 generate light of wavelengths corresponding to the kind.

### CITATION LIST

### Patent Document

Patent Document 1: Unexamined Published Japanese Patent Application No. 2011-142336

### SUMMARY OF THE INVENTION

### Problems to be Solved by the Invention

In a case where the technique of Patent Document 1 is used, the light source is covered by the sealing layers in which the semiconductor quantum dots are dispersed. The semiconductor quantum dots exist around the light source that generates heat. As a temperature inside the sealing layers gets higher, the fluorescence efficiency of the semiconductor quantum dots is lowered by the heat. The lowering of the fluorescence efficiency is said to be caused by vibration of crystal lattices of the semiconductor quantum dots due to the heat, generation of phonon scattering, and a loss of energy.

There is also a problem that the semiconductor quantum dots placed in a high temperature environment are degraded earlier than normal ones. That is, the semiconductor quantum dots dispersed in the sealing layer close to the light source are degraded earlier than the semiconductor quantum dots dispersed in the sealing layer away from the light source. As a result, whether it is assumed that the device will be used for a long time such as a lighting device, light quantities of wavelengths converted by the semiconductor quantum dots are lowered over time, and a disadvantage of causing color tone imbalance is generated.

The semiconductor quantum dots have such a property that the higher an environmental temperature is, the longer wavelengths of the generated fluorescent light are (shifted to the red side). Therefore, color of the fluorescent light emitted from the semiconductor quantum dots which are dispersed in the sealing layer close to the light source is changed, and there is a fear that a desired color tone cannot be obtained over the entire light emitting device.

The light emitting device utilizing the semiconductor is not limited to use of the semiconductor quantum dots but also has such a structure that a light emitting element serving as a light source and a gold wire are covered and protected by a sealing material using resin or the like. The sealing material protects the light emitting element from vibration, humidity, heat, and physical impact from the exterior.

However, there is a problem that a protection performance of the sealing material is worsened by adding the semiconductor quantum dots and an additive for dispersing the semiconductor quantum dots to resin serving as a material of the sealing material. As adverse effects on the sealing material, lowering of transparency and moisture permeability, blocking of hardening of the sealing material, and the like are found. As a result, the light emitting element is prone to breaking, and a disadvantage of shortening the life of the light emitting device is generated.

As described above, by forming the sealing layers in which the semiconductor quantum dots are dispersed around the light source, problems including trouble relating to the color tone such as the lowering of the fluorescence efficiency and degradation of the light emitting device are posed.

The present invention has been accomplished in view of the foregoing points, and an object thereof is to provide a light emitting device utilizing a semiconductor that has a sufficient light emitting characteristic and also has durability, and a manufacturing method of the same.

### Means for Solving the Problems

In order to attain the above object, a light emitting device utilizing a semiconductor of the present invention includes a base substrate in which a predetermined circuit pattern is provided, a light emitting element provided on the base substrate and electrically connected to the circuit pattern, a first layer sealing portion formed in at least a part on the light emitting element, the first layer sealing portion through which light emitted from the light emitting element is transmittable, and a second layer sealing portion formed in at least a part on the first layer sealing portion, the second layer sealing portion having at least one kind of semiconductor quantum dots.

Since the first layer sealing portion is formed in at least a part on the light emitting element, the light emitting element is protected, so that durability of the light emitting device utilizing the semiconductor can be improved.

Since the second layer sealing portion formed in at least a part on the first layer sealing portion, the second layer sealing portion having at least one kind of semiconductor quantum dots is provided, the light transmitted through the first layer can be converted into fluorescent light in accordance with the kind of semiconductor quantum dots. This indicates that light having a desired wavelength can be made by the configuration of the second layer sealing portion.

Since the light emitting element provided on the base substrate and electrically connected to the circuit pattern and the second layer sealing portion formed in at least a part on the first layer sealing portion, the second layer sealing portion having at least one kind of semiconductor quantum dots are provided, the light emitting element is also protected by the second layer sealing portion, so that durability of the light emitting device utilizing the semiconductor can be further improved.

In a case where a wavelength of light incident on the first layer sealing portion and a wavelength of light emitted from the first layer sealing portion are substantially the same, the wavelength of the light is hardly converted before and after transmission of the first layer sealing portion. The phrase “the wavelength of the incident light and the wavelength of the emitted light are substantially the same” described herein indicates that almost no semiconductor quantum dots are included in the first layer sealing portion. From this, a performance of the first layer sealing portion to protect the light emitting element becomes excellent, so that durability of the light emitting device utilizing the semiconductor can be improved.

In a case where the second layer sealing portion has two or more kinds of semiconductor quantum dots, light having a plurality of fluorescence wavelengths are emitted from the second layer sealing portion. From this, a plurality of light can be mixed and adjusted, so that various color tones can be reproduced. The phrase “different kinds” indicates that the semiconductor quantum dots emit light of different wavelengths.

In a case where a third layer sealing portion is formed in at least a part on the second layer sealing portion, the light emitting element is also protected by the third layer sealing portion, so that durability of the light emitting device utilizing the semiconductor can be furthermore improved.

In a case where the third layer sealing portion has semiconductor quantum dots that emit light having a wavelength shorter than a wavelength of light emitted from the semiconductor quantum dots which are included in the second layer sealing portion, the light converted and emitted from the second layer sealing portion is not absorbed by the semiconductor quantum dots dispersed in the third layer sealing portion. That is, due to no reduction in the third layer sealing portion, color tone imbalance is not easily caused.

In a case where the light emitting element emits light having a wavelength of 495 nm or less, the light having a short wavelength is incident on the sealing portions formed on the light emitting element. The semiconductor quantum dots have a property of absorbing light having a fixed wavelength or less. Thus, when a wavelength of light emitted from the light emitting element serving as a light source is short, the kind of utilizable semiconductor quantum dots is increased. The phrase “light having a short wavelength” indicates blue light or ultraviolet light.

In order to attain the above object, a manufacturing method of a light emitting device utilizing a semiconductor of the present invention includes a step of forming a first layer sealing material in at least a part on a predetermined circuit substrate including a light emitting element, the first layer sealing material through which light emitted from the light emitting element is transmittable, and a step of forming a second layer sealing material including at least one kind of semiconductor quantum dots in at least a part on the first layer sealing material.

Since the first layer sealing material is formed in at least a part on the predetermined circuit substrate including the light emitting element, a layer that protects the light emitting element from vibration, humidity, heat, and physical impact from the exterior can be formed, so that durability of the light emitting device utilizing the semiconductor can be improved.

Since the second layer sealing material including at least one kind of semiconductor quantum dots is formed, a layer capable of converting the light transmitted through the first layer into light having a wavelength corresponding to the kind of semiconductor quantum dots, so that light having a desired wavelength can be created.

Since the predetermined circuit substrate including the light emitting element and the second layer sealing material formed in at least a part on the first layer sealing material are provided, the light emitting element can also be protected by the second layer sealing material, so that durability of the light emitting device utilizing the semiconductor can be further improved.

In a case where the step of forming the first layer sealing material and the step of forming the second layer sealing material are performed by potting work, processing can be performed by a simple task of enclosing liquid resin in an object and hardening the resin. Thus, the light emitting device utilizing the semiconductor can be easily manufactured.

### Effects of the Invention

The light emitting device utilizing the semiconductor according to the present invention has a sufficient light emitting characteristic and also has durability.

In the manufacturing method of the light emitting device utilizing the semiconductor according to the present invention, the light emitting device utilizing the semiconductor which has a sufficient light emitting characteristic and also has durability can be manufactured.

### BRIEF DESCRIPTION OF THE DRAWINGS

FIG. 1 A schematic view showing one example of alight emitting device utilizing a semiconductor to which the present invention is applied.

FIG. 2 A schematic view of generation of fluorescent light in accordance with the kind of semiconductor quantum dots.

FIG. 3 A schematic view of manufacturing stages of a base substrate and a transmissive protection layer.

FIG. 4 A schematic view of manufacturing stages of a first fluorescent layer and a second fluorescent layer.

FIG. 5 A schematic view showing a modification of the light emitting device utilizing the semiconductor to which the present invention is applied.

FIG. 6 A schematic view of modifications of the generation of the fluorescent light in accordance with the kind of semiconductor quantum dots.

FIG. 7 A schematic view of modifications of the manufacturing stages of the base substrate and the transmissive protection layer.

FIG. 8 A schematic view of modifications of the manufacturing stages of the first fluorescent layer and the second fluorescent layer.

FIG. 9 A schematic view of a conventional light emitting device using semiconductor quantum dots.

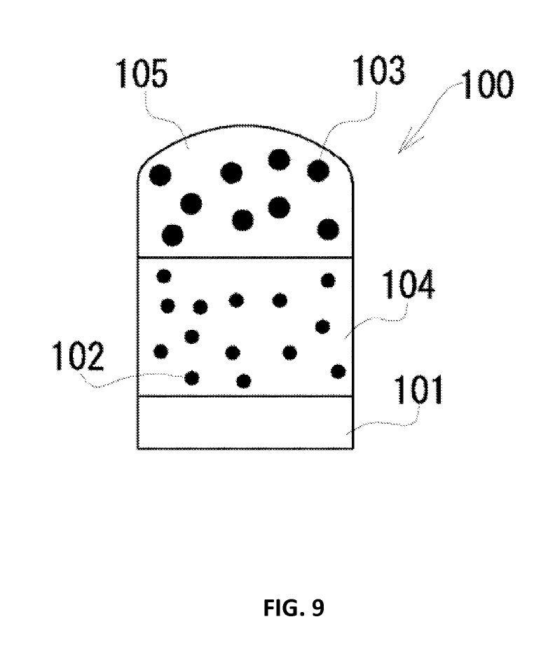

### MODE FOR CARRYING OUT THE INVENTION

Hereinafter, an embodiment of the present invention will be described with reference to the drawings, and the embodiment will be provided for understanding the present invention.

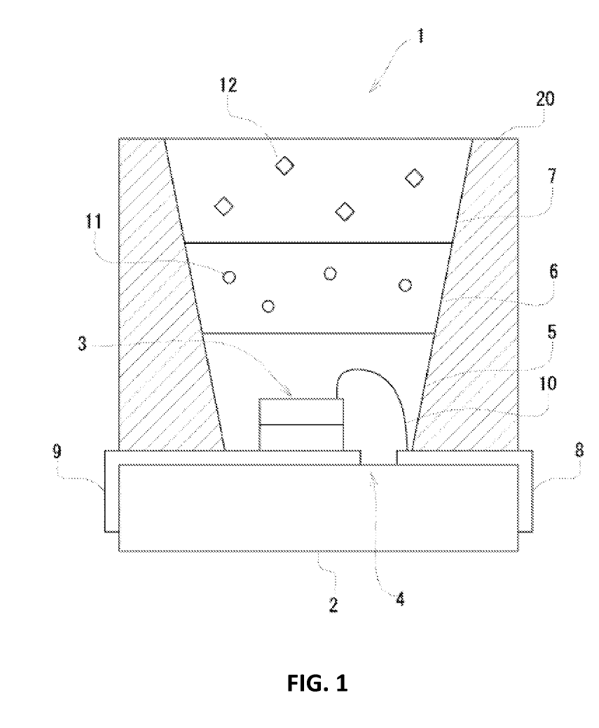

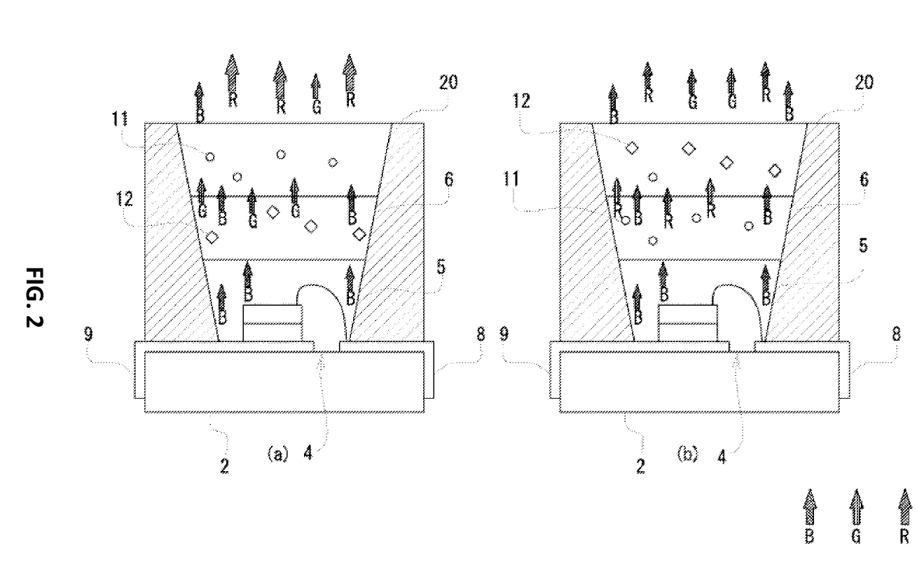

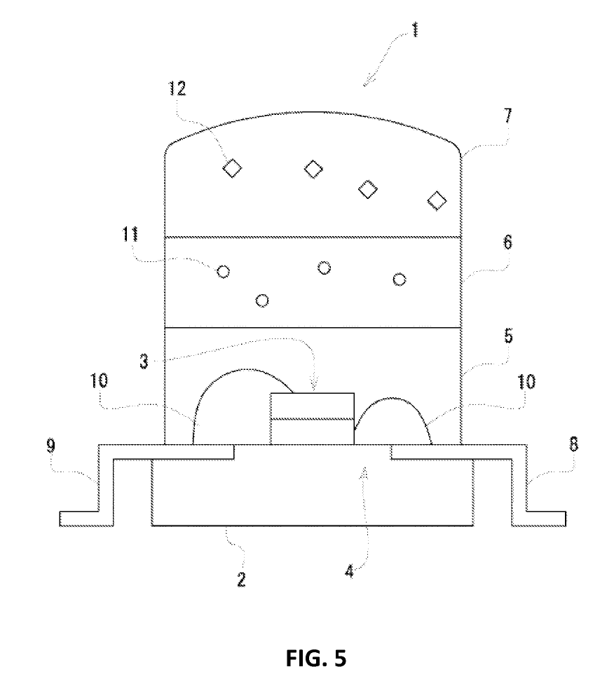

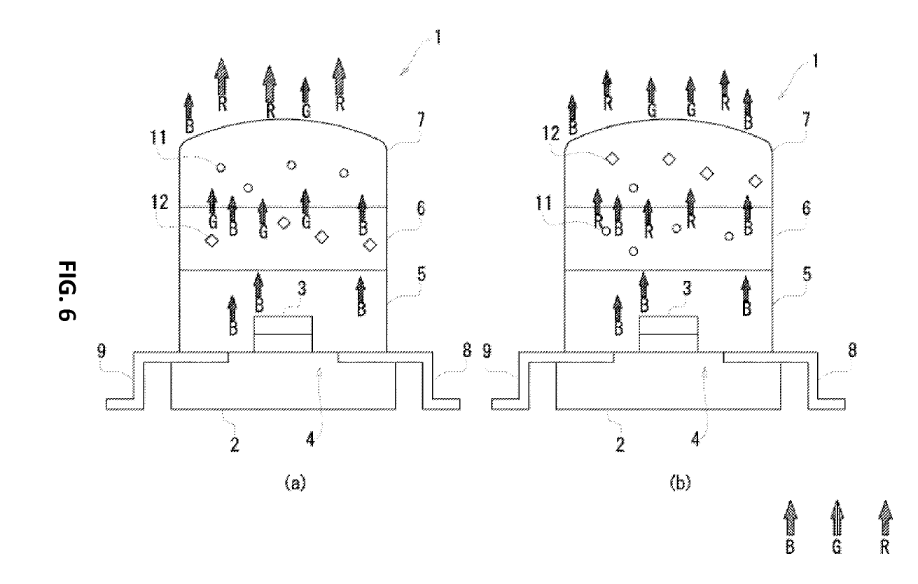

FIG. 1 is a schematic view showing one example of a light emitting device utilizing a semiconductor to which the present invention is applied. FIG. 2 is a schematic view of generation of fluorescent light in accordance with the kind of semiconductor quantum dots. FIG. 5 is a schematic view showing a modification of the light emitting device utilizing the semiconductor to which the present invention is applied. FIG. 6 is a schematic view of modifications of the generation of the fluorescent light in accordance with the kind of semiconductor quantum dots. In addition, an arrow B denotes blue light, an arrow G denotes green light, and an arrow R denotes red light in the figures.

As shown in FIG. 1, an LED light emitting apparatus 1 serving as one example of the light emitting device utilizing the semiconductor to which the present invention is applied includes a base substrate 2, a blue LED chip 3, a circuit pattern 4, a transmissive protection layer 5, a first fluorescent layer 6, and a second fluorescent layer 7.

First, the base substrate 2 is formed by a substantially flat plate-shape substrate made of plastic. The blue LED chip 3 is mounted on the base substrate 2 via a second lead electrode 9.

The circuit pattern 4 has electrically divided first and second lead electrodes 8 and 9. The first lead electrode 8 and the blue LED chip 3 are electrically connected by a gold wire 10. An insulating bank portion 20 (not shown in FIG. 5) is formed in a side part of the base substrate 2 and in an upper part of the first lead electrode 8 and the second lead electrode 9. The bank portion 20 is made of plastic as well as the base substrate 2.

The base substrate 2 is only required to be made of an insulating material, and the material is not necessarily limited to plastic. The shape is not limited to a substantially flat plate shape. The material of the bank portion 20 is also not limited to plastic and not limited to the same material as the base substrate 2.

In the circuit pattern 4, a circuit thereof is only required to be electrically connected to the blue LED chip 3, and the circuit pattern is not limited to the configuration that the electrically divided first and second lead electrodes 8 and 9 and the gold wire 10 are used.

A light source is not limited to the blue LED chip. An ultraviolet LED chip that emits light having a shorter wavelength or a blue laser diode may be used.

The material and the shape of the bank portion 20 are not particularly limited but the bank portion is only required to be insulating and has a shape of surrounding sealing layers.

Next, in an upper part of the wired base substrate 2, mainly a mounting region of the blue LED chip 3 as well as a surrounding region are covered by the transmissive protection layer 5. The transmissive protection layer 5 is made of epoxy based resin having translucency.

As shown in FIG. 1, in an upper part of the transmissive protection layer 5, the first fluorescent layer 6 having the substantially entire region of a formation region of the transmissive protection layer 5 is formed. The first fluorescent layer 6 is formed by a sealing material in which semiconductor quantum dots 11 are dispersed in epoxy based resin.

As shown in FIG. 1, in an upper part of the first fluorescent layer 6, a second fluorescent layer 7 having the substantially entire region of a formation region of the first fluorescent layer 6 is formed. The second fluorescent layer 7 is formed by a sealing material in which semiconductor quantum dots 12 are dispersed in epoxy based resin.

In the upper part of the base substrate 2, the region surrounding the blue LED chip 3 is not necessarily covered by the transmissive protection layer 5. The protection layer is only required to be partially formed so as to cover the mounting region of the blue LED chip 3. However, from the viewpoint of sufficiently protecting the blue LED chip 3 and the gold wire 10 from vibration, heat, and the like, in the upper part of the base substrate 2, mainly the mounting region of the blue LED chip 3 as well as the surrounding region are preferably covered by the transmissive protection layer 5.

The transmissive protection layer 5 is only required to be formed in such a manner that blue light emitted from the blue LED chip 3 is transmittable, and the material of the transmissive protection layer is not necessarily limited to epoxy based resin. In accordance with a purpose of use of the LED light emitting apparatus, a material having a characteristic of priority such as an electric characteristic, thermal conductivity, and toughness can be selected.

The first fluorescent layer 6 having the substantially entire region of the formation region of the transmissive protection layer 5 is not necessarily formed but the first fluorescent layer may be partially formed. However, from the viewpoint that blue light emitted from the blue LED chip 3 and transmitted through the transmissive protection layer 5 can be sufficiently absorbed, the first fluorescent layer 6 having the substantially entire region of the formation region of the transmissive protection layer 5 is preferably formed.

The material of the first fluorescent layer 6 is not limited to epoxy based resin. However, from the viewpoint of improving a light emitting characteristic of the LED light emitting apparatus, as the material to be used for the first fluorescent layer 6, a material with which a dispersing property of the semiconductor quantum dots is favorable is preferably selected.

The second fluorescent layer 7 is not necessarily formed. However, from the point that the semiconductor quantum dots can be divided by kind to emit light having different wavelengths and dispersed into the layers and the light emitting characteristic of the LED light emitting apparatus can be improved, the second fluorescent layer 7 is preferably formed together with the first fluorescent layer 6.

Even in a case where the second fluorescent layer is formed, the second fluorescent layer 7 having the substantially entire region of the formation region of the first fluorescent layer 6 is not necessarily formed but the second fluorescent layer may be partially formed. However, from the viewpoint that blue light emitted from the blue LED chip 3 can be sufficiently absorbed, the second fluorescent layer 7 having the substantially entire region of the formation region of the first fluorescent layer 6 is preferably formed.

The LED light emitting apparatus 1 serving as one example of the light emitting device utilizing the semiconductor to which the present invention is applied shown herein has a three-layer structure. However, the number of layers may be four or more. That is, the apparatus may have such a structure that another layer is further laminated on the second fluorescent layer 7.

The material of the second fluorescent layer 7 is not limited to epoxy based resin. However, from the viewpoint of improving the light emitting characteristic of the LED light emitting apparatus, as the material to be used for the second fluorescent layer 7, a material with which the dispersing property of the semiconductor quantum dots is favorable is preferably selected.

As the semiconductor quantum dots 11 and 12, core-shell type semiconductor quantum dots are used. The core-shell type semiconductor quantum dot has such a structure that a core serving as a light emitting part is doubly coated by a first shell and a second shell serving as protection films.

The core is made of CdSe (cadmium selenide), the first shell is made of ZnSe (zinc selenide), and the second shell is made of ZnS (zinc sulfide). In an interface between CdSe and ZnS, a ZnSe layer having a lattice constant in the middle between the both is epitaxially sandwiched. As another embodiment, CdS (cadmium sulfide), ZnSe, ZnCdSe solid solution, CdSeS solid solution, or ZnCdSeS solid solution is used for the core, CdS, ZnCdS solid solution, or ZnS is used as the first shell, and ZnCdS solid solution or ZnS is used as the second shell, and according to circumstances, ZnS is used as a third shell so as to form a four-layer structure.

The core-shell type semiconductor quantum dot is not limited to the structure that the core is doubly coated by the shells but a structure that the core is coated by one layer of a shell or coated by three layers of shells may be used. The materials of the core, the first shell, and the second shell are not necessarily limited to CdSe, ZnSe, and ZnS. However, from the point that distortion due to mismatch of lattice between CdSe and ZnS is eased by the existence of ZnSe and a physical property of the semiconductor quantum dot is improved, the core is preferably coated by two layers of the shells.

The semiconductor quantum dots 11 having a fluorescence wavelength of 660 nm (red) and the semiconductor quantum dots 12 having a fluorescence wavelength of 520 nm (green) are used. In addition, a wavelength of light emitted from the blue LED chip 3 is 450 nm (blue).

The kind of semiconductor quantum dots is not limited but an arbitrary one can be used according to a purpose of use. The quantity to be dispersed into the fluorescent layers is also not limited. However, in a case where a white LED is made, from the point that part of blue light emitted from the blue LED chip 3 is converted into green and red and white light uniformly having light of those colors can be emitted, the semiconductor quantum dots that emit fluorescent light of 660 nm (red) and 520 nm (green) are preferably used.

The layer into which the semiconductor quantum dots are to be dispersed by kind is not necessarily limited. However, there is an advantage of determining the layer into which the semiconductor quantum dots 11 and 12 are dispersed by the fluorescence wavelength emitted from the semiconductor quantum dots. Thus, description will be given below with reference to FIG. 1.

First, in FIG. 2(a), the semiconductor quantum dots 12 (fluorescence wavelength 520 nm: green) are included in the first fluorescent layer 6 on the side close to the light source, and the semiconductor quantum dots 11 (fluorescence wavelength 660 nm: red) are included in the second fluorescent layer 7. In this case, part of blue light (fluorescence wavelength 450 nm) emitted from the blue LED chip 3 is absorbed by the semiconductor quantum dots 12 of the first fluorescent layer 6 and converted into green light. Next, part of blue light and green light are absorbed by the semiconductor quantum dots 11 of the second fluorescent layer 7 and converted into red light.

Due to a property of a semiconductor quantum dot to absorb energy of light having a wavelength shorter than a wavelength of fluorescent light emitted by the semiconductor quantum dot itself, part of green light emitted from the first fluorescent layer 6 is also absorbed by the second fluorescent layer 7 and converted into red. As a result, in an LED light emitting apparatus shown in FIG. 2(a), red light is strongly emitted and green light is weakened. Thus, color tone imbalance is easily caused over the entire LED light emitting apparatus.

Meanwhile, in FIG. 2(b), the semiconductor quantum dots 11 (fluorescence wavelength 660 nm: red) are included in the first fluorescent layer 6 on the side close to the light source, and the semiconductor quantum dots 12 (fluorescence wavelength 520 nm: green) are included in the second fluorescent layer 7. In this case, part of blue light is absorbed by the semiconductor quantum dots 11 of the first fluorescent layer 6 and converted into red light. Next, the semiconductor quantum dots 12 of the second fluorescent layer 7 absorb only part of blue light and emit green light. Red light emitted from the first fluorescent layer 6 is not absorbed. Therefore, in the LED light emitting apparatus shown in FIG. 2(b), blue light, green light, and red light are emitted in a balanced manner.

Hereinafter, a manufacturing method of the LED light emitting apparatus 1 will be described.

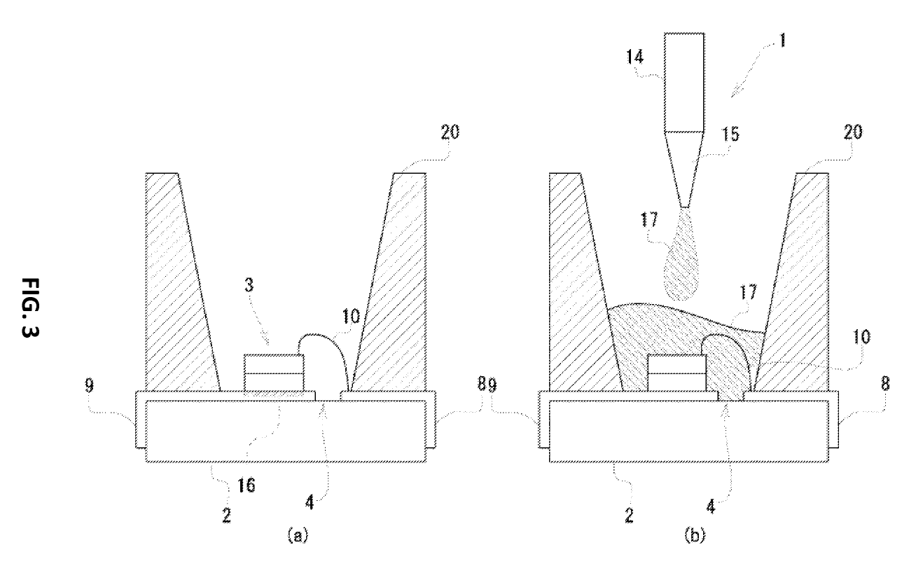

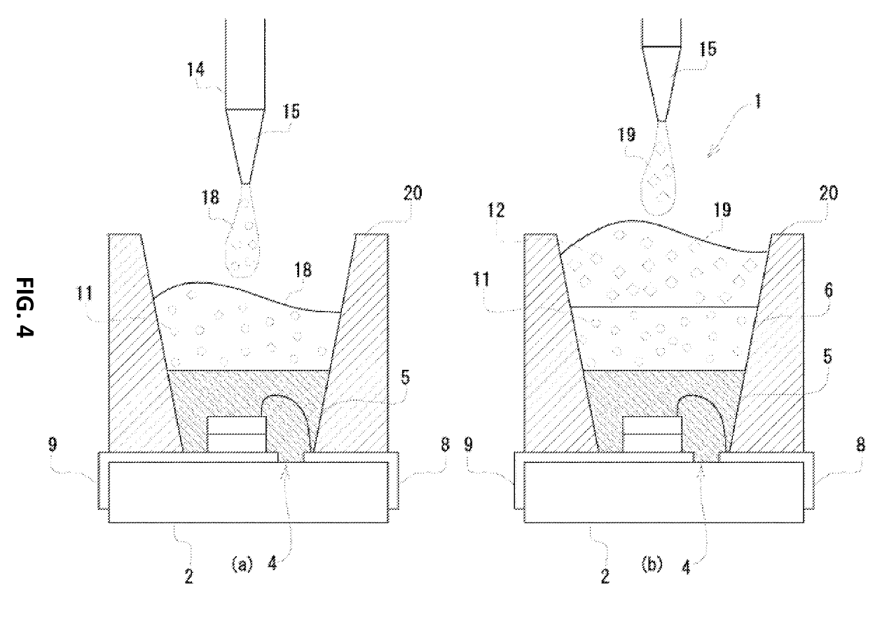

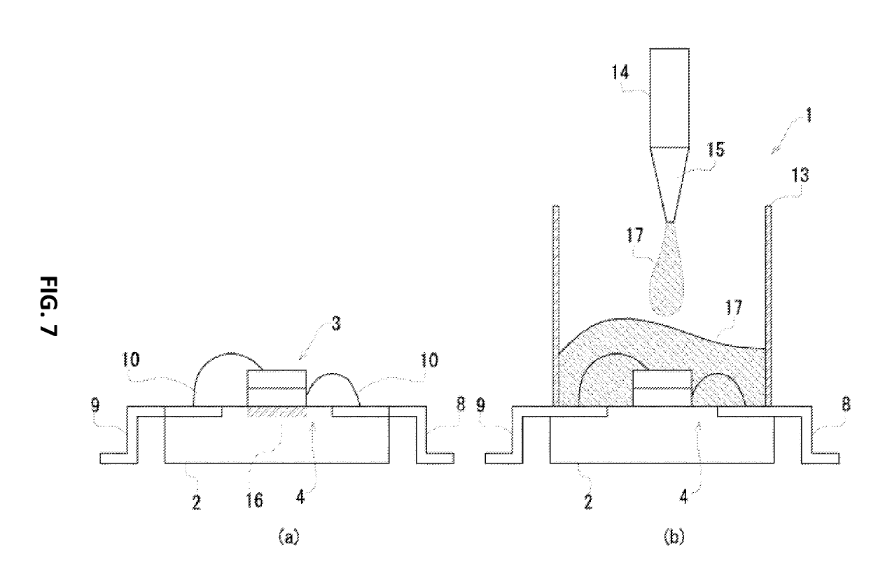

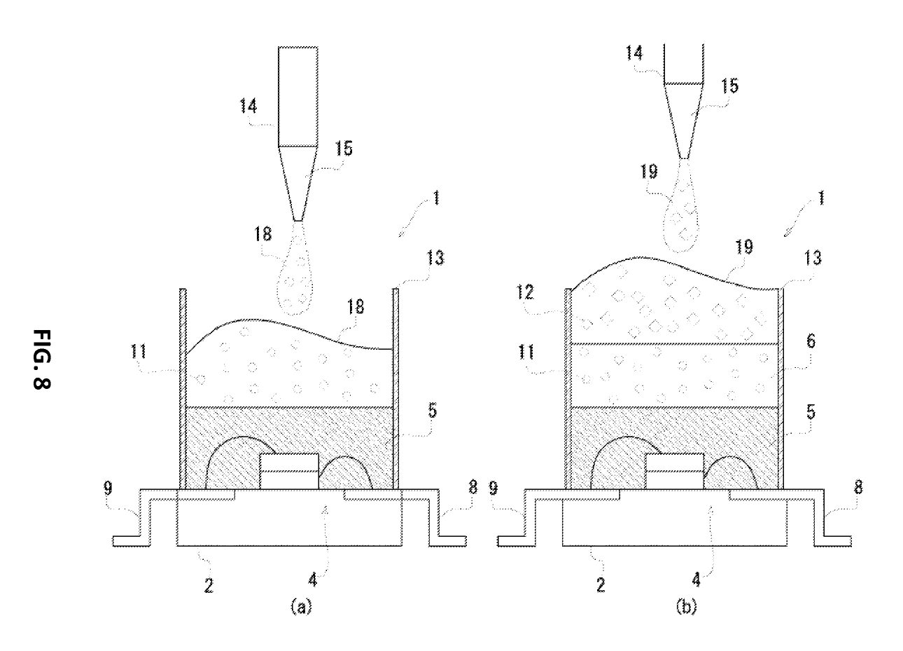

FIG. 3 is a schematic view of manufacturing stages of the base substrate and the transmissive protection layer. FIG. 4 is a schematic view of manufacturing stages of the first fluorescent layer and the second fluorescent layer. FIG. 7 is a schematic view of modifications of the manufacturing stages of the base substrate and the transmissive protection layer. FIG. 8 is a schematic view of modifications of the manufacturing stages of the first fluorescent layer and the second fluorescent layer.

First, as the blue LED chip 3, plural chips formed on a wafer are separated and used. As the semiconductor material of the blue LED chip 3, GaN (gallium nitride), Al₂O₃ (sapphire), SiC (silicon carbide), and GaAs (gallium arsenide) can be used. The wafer is formed by letting N type and P type crystal layers grow on a substrate using these semiconductor materials. As a method of letting the crystals grow, liquid phase epitaxial growth in which growth is developed with use of a temperature difference in a liquid phase, or the like can be used. A commercially available wafer may be used.

The base substrate 2 can be made by a known manufacturing method of a printed substrate. As shown in FIG. 3(a), the first and second lead electrodes 8 and 9 processed into an electrode shape and made of aluminum are arranged on a plastic substrate. On the arranged first and second lead electrodes 8 and 9, the bank portion 20 (not shown in FIG. 7(a)) made of the same plastic material as the substrate is mounted, so that the lead electrodes are sandwiched by the substrate and the bank portion 20. The substrate and the bank portion 20 are welded by ultrasonic treatment. In the circuit pattern 4, the electrically divided first and second lead electrodes 8 and 9 are formed.

On the electrode, a paste 16 of heated Ag (silver) is applied, and the blue LED chip 3 is arranged on the paste 16. The paste 16 is hardened, so that the blue LED chip 3 is fixed on the electrode.

The first lead electrode 8 is wire-bonded to the blue LED chip 3 by the gold wire 10, so that the first lead electrode 8 and the blue LED chip 3 are electrically connected. Thereby, a voltage can be applied to the blue LED chip 3. In the above steps, the circuit substrate including the LED chip is completed.

Next, the above circuit substrate is sealed with use of the transmissive protection layer 5. The transmissive protection layer 5 is made of epoxy resin 17 through which blue light emitted from the blue LED chip 3 can be transmitted. Sealing is made by a potting method and as the epoxy resin 17, thermosetting liquid epoxy resin is used.

The method of sealing with resin is not limited to the potting method but any method may be used as long as sealing can be made. Hardening of the resin is not limited to thermal hardening but any method may be used as long as hardening can be made. For example, ultraviolet curable resin may be used. The above points are applied not only to the transmissive protection layer 5 but also to the first fluorescent layer 6 and the second fluorescent layer 7.

As shown in FIG. 3(b), the liquid epoxy resin 17 is dropped down from an upper part of the blue LED chip 3 and the gold wire 10. A syringe 14 filled with the epoxy resin 17 is used for dropping, and the resin is dropped down from a leading end part of a needle 15 provided in the syringe 14. A charging quantity of the resin is appropriately selected so that the transmissive protection layer 5 has a desired thickness. In FIG. 7(b), a holding portion 13 is formed and the resin is dropped down to a surrounded space.

Next, the substrate in a state where the epoxy resin 17 is dropped is heated and the resin is hardened. A heater (not shown) is used for hardening the resin and heating can be made by a far-infrared heater or an IH heater. The epoxy resin 17 is thermally hardened under a condition of 150° C. for five hours. The hardened epoxy resin 17 serves as a protection layer of the blue LED chip 3 and the gold wire 10.

Successively, a manufacturing method of the first fluorescent layer 6 and the second fluorescent layer 7 will be described.

The semiconductor quantum dots 11 and 12 included in the fluorescent layers are adjusted as solutions. The core-shell type semiconductor quantum dots can be manufactured by, for example, the methods described in Unexamined Published Japanese Patent Application No. 2003-225900 and WO2005/023704. A solution containing materials such as Cd and Zn passes through the interior of a heated micro flow passage so as to form nuclear particles and a coating structure. By such a manufacturing method using a microreactor, the core-shell type semiconductor quantum dots are obtained.

Next, the core-shell type semiconductor quantum dots are dispersed into a volatile solvent after refinement and concentration adjustment, so that a fluorescent body solution is obtained. In a case where the fluorescent body solution is prepared, according to need, surface treatment is performed with use of phosphine and amine compounds and fluorine and silicon resin monomers and polymers and the like. Thereby, the physical property and durability of the semiconductor quantum dots are improved.

Successively, the fluorescent body solution is mixed with a main agent or a hardening agent of a two pack type potting agent. The two pack type potting agent can be appropriately selected in accordance with the kind and the dispersing property of the semiconductor quantum dots. After mixing the two pack type potting agent with the main agent or the hardening agent, defoaming treatment is performed in vacuum to remove foam inside the mixed solution, so as to obtain a sealing material to be used for the first fluorescent layer 6 and the second fluorescent layer 7.

Sealing by the first fluorescent layer 6 and the second fluorescent layer 7 is performed similarly to sealing by the transmissive protection layer 5.

First, as shown in FIG. 4(a), from the upper part of the transmissive protection layer 5, thermosetting epoxy resin 18 mixed with the fluorescent body solution including the semiconductor quantum dots 11 is dropped down. The epoxy resin 18 filled in the syringe 14 covers the upper part of the transmissive protection layer 5. A charging quantity of the resin is appropriately selected so that the first fluorescent layer 6 has a desired thickness.

Next, the substrate in a state where the epoxy resin 18 is dropped is heated and the resin is hardened. The resin is hardened under a condition of a temperature of 150° C. for five hours. A kind of resin with which the dispersing property of the semiconductor quantum dots is favorable is preferably selected. The hardened epoxy resin 18 serves as the first fluorescent layer.

Further, the second fluorescent layer 7 is formed on an upper part of the first fluorescent layer 6 formed in the above step. As shown in FIG. 4(b), from the upper part of the first fluorescent layer 6, thermosetting epoxy resin 19 mixed with the fluorescent body solution including the semiconductor quantum dots 12 is dropped down. The epoxy resin 19 filled in the syringe 14 covers the upper part of the first fluorescent layer 6. A charging quantity of the resin is appropriately selected so that the second fluorescent layer 7 has a desired thickness.

Next, the substrate in a state where the epoxy resin 19 is dropped is heated and the resin is hardened. The resin is hardened under a condition of a temperature of 150° C. for five hours. A kind of resin with which the dispersing property of the semiconductor quantum dots is favorable is preferably selected. The hardened epoxy resin 19 serves as the second fluorescent layer. Thereby, the LED light emitting apparatus 1 as shown in FIG. 1 is completed.

In addition, in the manufacturing method of the first fluorescent layer 6 and the second fluorescent layer 7, the resin including the semiconductor quantum dots in advance is used for the potting method. As another manufacturing method, there is also a method of supplying only resin such as epoxy resin by the potting method and hardening the resin after applying or blowing a fluorescent body solution including semiconductor quantum dots onto an upper surface of a resin layer. A supply method of the resin is not limited to the potting method and hardening of the resin is also not limited to thermal hardening. The manufacturing method of the fluorescent layers can be selected in consideration with the dispersing property of the semiconductor quantum dots in the resin to be used.

In the LED light emitting apparatus serving as one example of the light emitting device utilizing the semiconductor to which the present invention is applied, part of blue light emitted from the blue LED chip can be converted into red and green by the semiconductor quantum dots included in the first fluorescent layer and the second fluorescent layer, so that light recognized as white light can be emitted from the entire LED light emitting apparatus.

Since the blue LED chip serving as a heat source is covered by the epoxy resin transmissive protection layer, a light emitting characteristic of the semiconductor quantum dots dispersed in the layers positioned on the upper part of the transmissive protection layer is not easily deteriorated. As a result, light emitting efficiency of the entire LED light emitting apparatus is improved. Since the blue LED chip is also securely protected by the resin excellent in a protection performance, durability of the LED light emitting apparatus is also improved.

In such a way, the light emitting device utilizing the semiconductor to which the present invention is applied has a sufficient light emitting characteristic and also has durability.

In the manufacturing method of the light emitting device utilizing the semiconductor according to the present invention, the light emitting device utilizing the semiconductor having a sufficient light emitting characteristic and also having durability can be manufactured.

### DESCRIPTION OF SYMBOLS

1: LED light emitting apparatus
2: Base substrate
3: Blue LED chip
4: Circuit pattern
5: Transmissive protection layer
6: First fluorescent layer
7: Second fluorescent layer
8: First lead electrode
9: Second lead electrode
10: Gold wire
11: Semiconductor quantum dot
12: Semiconductor quantum dot
13: Holding portion
14: Syringe
15: Needle
16: Paste
17: Epoxy resin
18: Epoxy resin
19: Epoxy resin
20: Bank portion
B: Arrow indicating blue light
G: Arrow indicating green light
R: Arrow indicating red light

1. A light emitting device comprising:
a base substrate in which a predetermined circuit pattern is provided;
a light emitting element provided on the base substrate and electrically connected to the circuit pattern;
a first layer sealing portion formed in at least a part on the light emitting element, the first layer sealing portion through which light emitted from the light emitting element is transmittable; and
a second layer sealing portion formed in at least a part on the first layer sealing portion, the second layer sealing portion having at least one kind of semiconductor quantum dots.

2. The light emitting device utilizing the semiconductor according to claim 1, wherein
a wavelength of light incident on the first layer sealing portion and a wavelength of light emitted from the first layer sealing portion are substantially the same.

3. The light emitting device utilizing the semiconductor according to claim 1, wherein
the second layer sealing portion has two or more kinds of semiconductor quantum dots.

4. The light emitting device utilizing the semiconductor according to claim 1, comprising:
a third layer sealing portion formed in at least a part on the second layer sealing portion, the third layer sealing portion having semiconductor quantum dots that emit fluorescent light having a wavelength shorter than a wavelength of fluorescent light emitted from the semiconductor quantum dots which are included in the second layer sealing portion.

5. The light emitting device utilizing the semiconductor according to claim 1, wherein
the light emitting element emits light having a wavelength of 495 nm of less.

6. A manufacturing method of a light emitting device utilizing a semiconductor, comprising:
a step of forming a first layer sealing material in at least a part on a predetermined circuit substrate including a light emitting element, the first layer sealing material through which light emitted from the light emitting element is transmittable; and
a step of forming a second layer sealing material including at least one kind of semiconductor quantum dots in at least a part on the first layer sealing material.

7. The manufacturing method of the light emitting device utilizing the semiconductor according to claim 6, wherein
the step of forming the first layer sealing material and the step of forming the second layer sealing material are performed by potting work.
